(19) United States
(12) Patent Application Publication
(10) Pub. No.: US 2018/0254300 A1
(43) Pub. Date: Sep. 6, 2018

(54) PHOTODIODE MATRIX WITH ISOLATED CATHODES

(71) Applicant: NEW IMAGING TECHNOLOGIES, Verrieres Le Buisson (FR)

(72) Inventor: Yang NI, Palaiseau (FR)

(21) Appl. No.: 15/755,516

(22) PCT Filed: Aug. 26, 2016
(86) PCT No.: PCT/FR2016/052129

§ 371 Date: Feb. 26, 2018

(30) Foreign Application Priority Data
Aug. 26, 2015 (FR) 1557925

(51) Int. Cl. H01L 27/146

(52) U.S. Cl. CPC H01L 27/14643; H01L 27/14694; H01L 27/1463

(57) ABSTRACT

The invention relates to a photodiode matrix and to the method for manufacturing same, said matrix comprising a substrate (4) of indium phosphide an active layer (5) of indium gallium arsenide above the substrate (4), a buried region (8) between the substrate (4) and the active layer (5), and an upper layer (6) made of indium phosphide above the active layer (5), a photodiode anode made up of a doped region (12), said doped region (12) extending from the upper layer (6) into the active layer (5) without reaching the buried region (8), said doped region (12) defining a plurality of cathode areas (13) of the upper layer (6) isolated from one another by the doped region (12).

### FIELD OF THE INVENTION

The invention relates to photodiode arrays and more particularly to photodiode arrays having layers of indium gallium arsenide (InGaAs) and indium phosphide (InP), and to the manufacturing method thereof.

One of the methods for manufacturing a photodiode array in semiconductor materials with narrow band gap (often for detection in infrared light) is to insert the active detection layer with narrow band gap between two semiconductor materials with wide band gap. The two semiconductor layers with wide band gap consist of efficient protection/passivation whilst remaining transparent to the radiation wavelength intended to be detected by the photodiodes.

In addition, with suitable doping, the two heterojunctions between the active layer and the two protection/passivation layers confine photoelectric charges within the active detection layer and improve the quantum yield of the photodiode thus formed.

An InGaAs photodiode is a typical example of this physical structure. The active detection layer is consisting of InGaAs material to obtain an adjustable band gap as a function of the indium and gallium composition of the InGaAs material, ideal for operating in the Short WaveInfraRed band (SWIR) in the order of 0.9 to 3 μm.

Indium phosphide and indium gallium arsenide share the same face-centred crystalline structure. The most widely used composition is In_{0.53}Ga_{0.47}As. The size of the crystal lattice is then comparable with that of the InP substrate, in particular the lattice parameters. This crystalline compatibility allows epitaxial growth of an active InGaAs layer of excellent quality on an InP substrate. The band gap of In_{0.53}Ga_{0.47}As is about 0.73 eV, capable of detection up to a wavelength of 1.68 μm in the SWIR band. It is the subject of increasing interest in fields of application such as spectrometry, night vision, sorting of used plastics, etc.

The two protection/passivation layers are generally consisting of InP. More especially, since the In_{0.53}Ga_{0.47}As composition has the same crystal lattice size as InP, this allows a very low dark current as from ambient temperature.

Up until now, the best configuration of InGaAs photodiodes is consisting of selective doping areas in zinc Zn, of P-type, on epitaxial InP/InGaAs/InP layers of N-type, to constitute the anodes of the photodiodes which collect the charges. Such a configuration is said to be “P-on-N”.

FIG. 1 illustrates the physical structure of an array 1 of photodiodes with P-on-N configuration. An active layer 5 composed of InGaAs is sandwiched between two InP layers. The lower layer constitutes the substrate 4 on which the InGaAs layer is formed by complex MO-CVD epitaxy. This InGaAs layer is then protected by a thin upper layer 6 composed of InP, also deposited by epitaxy. The InP layers are generally of silicon-doped N-type. The active layer 5 of InGaAs can be slightly N-doped or remain near-intrinsic. Therefore, the two upper/lower InP layers and the active layer 5 in InGaAs form the common cathode of the photodiodes in this array.

FIG. 2 illustrates an InGaAs image sensor consisting of an array 1 of InGaAs photodiodes flip-chip connected to a read-out circuit 2. In an InGaAs array sensor, the photodiode array is connected to a read-out circuit generally made of silicon to read the photoelectric signals generated by these InGaAs photodiodes. This interconnection is generally obtained via flip-chip technology using indium beads 7, as illustrated in FIG. 2. SWIR radiation 9 arrives at the photodiode array through the substrate 4 of indium phosphide that is transparent in this optical band.

Another solution to prepare a photodiode array is a so-called “N-on-P” configuration, where the anodes of the photodiodes which collect the charges are of N-type, on epitaxial layers of P-type. However, it is difficult to work with a P-type substrate, and selective doping of N-type is ill controlled. U.S. Pat. No. 8,610,170 B2 proposes an alternative solution for an “N-on-P” configuration illustrated in FIGS. 3 and 4, where the cathodes are not formed by N-type doping but by insulating areas of a layer of N-type with areas of P-type.

FIG. 3 gives a cross-sectional view of a simplified photodiode array, whilst FIG. 4 gives a perspective view of such an array. With this approach, a buffer layer 108 that is Zn-doped (P-type) is inserted between the photosensitive layer 102 of InGaAs (N-type) and the InP substrate 101 of N-type. A Zn doping area 104 of P-type of grid shape (seen from overhead) is formed in the photosensitive layer 102 from the upper InP layer 103 of N-type as far as a depth reaching the buried buffer layer 108. This grid pattern forms N-type areas individually surrounded by the doping area 104 and by the buffer layer 108 and consisting of the portions of the upper layer 103 and the photosensitive layer 102 that are not Zinc-doped. These areas form the cathodes of so-called “N-on-P” photodiodes and are each provided with a contact electrode 106. With this configuration it is possible to insulate the cathodes physically from one another. The term PN junction insulation is used.

However, this approach requires deep depth of diffusion for Zn doping when forming the area 104; the Zn dopants must enter into the entire thickness of the photosensitive layer 102 to reach the buried buffer layer 108. Yet diffusion of dopants does not only take place depth-wise, but also laterally parallel to the surface of the array. Therefore, the deeper the diffusion of Zn dopants, the wider it is.

For example, to maintain good quantum yield, the thickness of the photosensitive layer 102 of InGaAs is preferably at least 3 to 5 μm. A shallower depth reduces the efficacy of photon absorption. For such a thickness of 3 to 5 μm, lateral diffusion of Zn dopants around the incident area of doping i.e. the exposed areas of the mask used for diffusion, is 6 to 10 μm. It is therefore ascertained that the width of the portions of area 104 surrounding a cathode will be larger than 10 μm, i.e. more than twice the thickness of the photosensitive layer 102.

As a result, the pitch of the photodiodes on the surface of the array must be sufficiently large to allow an area 104 of Zn doping having portions of large width, and this approach therefore does not allow a photodiode array to be obtained having a high density of photodiodes on the surface thereof.

In addition, this lateral extension of portions of area 104 brings a related reduction in the surface area occupied by the cathodes insulated by said portions of said area 104. Returning to the preceding example, for a photodiode pitch of 10 to 15 μm, the size of the cathode becomes small in relation to the width of the portions of area 104. Yet the lifetime of charge carriers in the Zn diffusion area 104 is fairly short on account of the high doping level. Collecting efficiency therefore becomes reduced.

This same patent proposes another embodiment to form trenches around cathode areas of a photodiode before diffusing zinc. These trenches allow Zn diffusion to reach the buried buffer layer 108 faster, and therefore allow limiting of the lateral extension of this diffusion. However, experience has shown that damage related to the etching of these trenches considerably deteriorates the quality of the photodiodes, particularly in terms of dark current.

### SUMMARY OF THE INVENTION

It is one objective of the invention to propose a photodiode array and the method for manufacture thereof, allowing insulating of the cathodes from one another whilst maintaining good quantum yield and good surface yield of the array. With the invention it is possible to obtain “N-on-P” photodiodes having improved photoelectric performance and compatible with a reduction in the pitch of the photodiodes, allowing a reduction in costs and increased resolution of InGaAs photodiode arrays.

For this purpose, there is proposed a photodiode array comprising:
an indium phosphide substrate;
an active layer of indium gallium arsenide InGaAs above the substrate and having conductivity of the first type;
an upper layer in indium phosphide above the active layer and having conductivity of the first type;
a buried region defined by doping of the second type, at the interface between the substrate and the active layer;
   said array comprising an anode common to the photodiode array, formed by a doped region of the second type in the upper layer and in the active layer, said doped region extending from the upper layer as far as the active layer without reaching the buried region, said doped region and said buried region being separated by the active layer by a nonzero distance,
   said doped region delimiting several cathode areas free of the second type doping in the upper layer, each of said cathode areas being continuously separated from the other cathode areas by the doped region.

By doped region of the second type is meant a region of a material comprising dopants of the second type resulting for example from diffusion thereof in said material, in higher concentration than any dopants of the first type.

The invention is advantageously completed by the following characteristics taken alone or in any technically possible combination:
an anode space charge area extends into the active layer from each interface between the doped region of the second type and the active layer, and a buried space charge area extends into the active layer from the interface between said active layer and the buried region, the anode space charge area and the buried space charge area joining together in the active layer, so that areas of the active layer underneath the cathode areas of the upper layer are insulated from one another continuously by said space charge areas;
each cathode area of the upper layer is connected to bias means adapted to apply a first voltage to said cathodes, and wherein the doped area is connected to bias means adapted to apply a second voltage to said doped area, the first voltage and the second voltage being of different values, the difference in value between the first voltage and the second voltage determining the extension of the anode space charge area into the active layer, the first voltage varying over a range between a minimum cathode voltage and a maximum cathode voltage, the second voltage being chosen to be sufficiently lower than the first voltage so that the anode space charge area extends into the active layer as far as the buried space charge area;
each cathode area of the upper layer is connected to bias means adapted to apply a first voltage to said cathodes, and the buried region is connected to bias means adapted to apply a third voltage to said buried region, the first voltage and the third voltage having different values, the difference in value between the first voltage and the third voltage determining the extension of the buried space charge area into the active layer, the first voltage varying over a range between a minimum cathode voltage and a maximum cathode voltage, the third voltage being chosen to be sufficiently lower than the first voltage so that the buried space charge area extends into the active layer as far as the anode space charge area;
the difference in value between the minimum cathode voltage and the second voltage is lower than the difference in value between the minimum cathode voltage and the third voltage;
a distance separating the anode space charge area and the buried space charge area in the active layer in the absence of polarization is shorter than twice the minimum distance between:
   a distance over which the anode space charge area extends into the active layer from the interface between the doped region and said active layer in the absence of polarization; and
   a distance over which the buried space charge area extends into the active layer from the interface between the buried region and said active layer in the absence of polarization;
the cathode areas of the upper layer that are delimited by the doped region of the second type, are doped with dopants of the first type;
the doped region of the second type extends into the active layer from the upper layer over a depth less than one quarter of the thickness of said active layer.

The invention also relates to a sensor comprising a photodiode array of the invention, and a read-out circuit connected to contacts of the cathode areas to read the photodiodes of said array.

The invention also relates to a method for manufacturing an array according to one of the preceding claims, comprising the steps of:
providing an indium phosphide substrate having conductivity of the first type;
forming a buried region having conductivity of the second type above said substrate;
forming an active layer having conductivity of the first type above the buried region;
forming an upper layer having conductivity of the first type above the active layer;
positioning a mask defining a plurality of masking areas on the surface of the upper layer and a plurality of exposed areas on the surface of the upper layer;
diffusing dopants of the second type through the exposed areas into the upper layer and into the active layer to define a doped region of the second type facing said exposed areas so that the doped region extends from the upper layer as far as into the active layer without reaching the buried region, said doped region and said buried region being separated by a nonzero distance, said doped region delimiting several cathode areas of the upper layer facing the masking areas, each of said cathode areas being separated continuously from the other cathode areas by the doped region.

### BRIEF DESCRIPTION OF THE FIGURES

Other characteristics and advantages of the invention will become apparent from the following description that is solely illustrative and nonlimiting. This description is to be read in connection with the appended drawings in which:

FIG. 1, already commented upon, is a diagram illustrating a cross-sectional view of a simplified photodiode array structure of P-on-N configuration in the prior art;

FIG. 2, already commented upon, is a diagram illustrating the connection of the P-on-N array in FIG. 1 with a read-out circuit;

FIG. 3, already commented upon, is a diagram giving a cross-sectional view of a simplified, photodiode array structure of N-on-P configuration in the prior art;

FIG. 4, already commented upon, is a diagram giving a perspective view of an array having a structure similar to that in FIG. 3;

FIG. 5 is a diagram giving a cross-sectional view of a simplified photodiode array according to one possible embodiment of the invention, of N-on-P configuration;

FIG. 6 is a diagram giving a cross-sectional view along AA of the array in FIG. 5;

FIGS. 7 and 8 are diagrams illustrating cross-sectional views of a simplified photodiode array according to one possible embodiment of the invention, when different voltages are applied;

FIGS. 9a to 9h are diagrams illustrating different steps for the manufacturing of a photodiode array according to one possible embodiment of the invention.

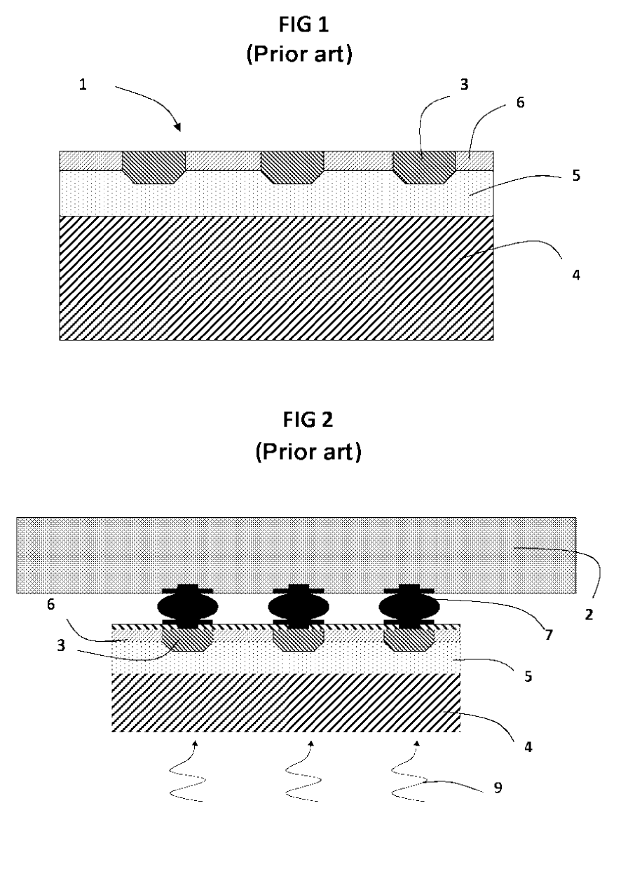

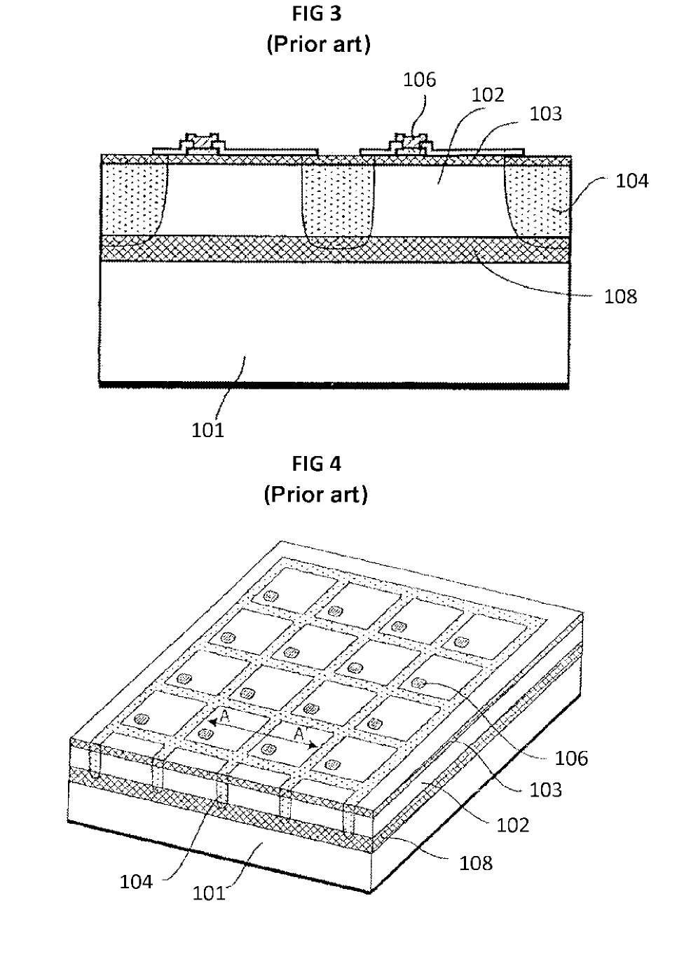

In the different Figures, same references designate similar elements.

### DETAILED DESCRIPTION

In the following description, as an illustrative example, the first type of conductivity is conductivity of N-type, whilst the second type of conductivity is conductivity of P-type. It would also be possible, by adapting the components, that the first type of conductivity is conductivity of P-type whilst the second type of conductivity is conductivity of N-type.

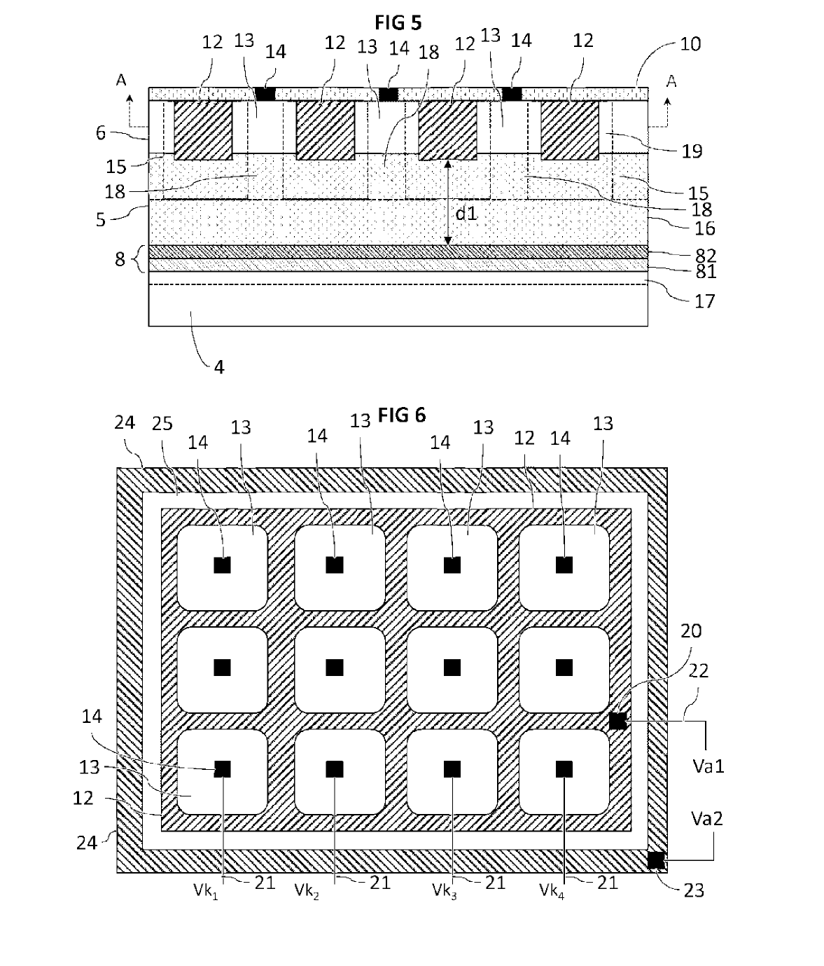

With reference to FIGS. 5 and 6, a photodiode array according to one embodiment of the invention comprises a substrate 4 of indium phosphide InP having conductivity of N-type, preferably N-doped i.e. with dopant elements of N-type such as silicon. For example, the concentration in terms of charge carriers of the substrate 4 may be between 10¹⁷ and 10¹⁹ cm⁻³.

The array also comprises an active layer 5 of indium gallium arsenide InGaAs constituting a photosensitive layer above the substrate 4. The thickness of the active layer is preferably greater than 3 μm and preferably less than 5 μm. The active layer 5 may be non-doped (intrinsic) or N-doped at low concentration e.g. a concentration of dopants of between 10¹³ and 10¹⁷ cm⁻³,

Between the substrate 4 and the active layer 5, i.e. at their interface, there is a buried region 8 consisting of a P-doped area e.g. consisting of diffusion of zinc. The thickness of the buried region 8 is preferably greater than 0.01 μm and preferably less than 1 μm. If the thickness of the buried region 8 is too great this could absorb too much light.

The buried region 8 can be formed in several manners. As illustrated in FIG. 6, it may comprise a surface area 81 of the substrate 4 that has been P-doped, for example by zinc diffusion, and an epitaxial buffer layer 82 of InGaAs on the substrate 4, also P-doped with the same doping operation as for the surface area 81 of the substrate 4, or via a separate doping operation. Another solution is to P-dope solely the surface area 81 of the substrate 4, and to form a buffer layer and/or active layer 5 thereupon, the doping of these layers at the interface with the substrate 4 taking place via thermal diffusion of the dopants. The combination of the surface area 81 of the substrate 4 with the layer 82 above said surface area 81 of the substrate 4 thereby constitutes a buried region 8 of P-type, defined as having doping of P-type in relation to the remainder of the substrate 4 and active layer 5 that are of N-type.

The array, above the active layer 5, also comprises an upper layer 6 of indium phosphide having conductivity of N-type. The thickness of the upper layer 6 is preferably greater than 0.1 μm and preferably less than 1 μm. The upper layer 6 can be N-doped for example at a dopant concentration of between 10¹⁵ and 10¹⁸ cm⁻³, typically of silicon. Preferably, the doping of the upper layer 6 is stronger than that of the active layer 5 by a factor of at least 10.

Insofar as some compositions of the active layer 5 have a crystal size close to that of an InP layer, especially the composition In_{0.53}Ga_{0.47}As, the superimposition of an InP layer over the active layer 5 allows dark current to be reduced to a very low level, as from ambient temperature. Similarly, a passivation layer 10 in dielectric material such as silicon nitride can be provided on the surface of the array above the upper layer 6.

The array also comprises at least one doped region 12 of P-type in the upper layer 6 and in the active layer 5. More specifically, the doped region 12 extends from the upper layer 6 as far as into the active layer 5 without reaching the buried region 8 or the substrate 4. The doped region 12 passes through the thickness of the upper layer 6 but does not pass through the thickness of the active layer 5. This doped region 12 of P-type forms an anode common to the photodiode array, that is therefore shared by several photodiodes and even preferably by all the photodiodes.

Preferably, the doped region 12 of P-type extends into the active layer 5 from the upper layer 6 over a depth that is less than one quarter of the thickness of said active layer 5, and further preferably less than one eighth of the thickness of said active layer 5. For example, for an active layer 5 having a thickness of 3 μm to 5 μm it is sufficient that the doped region 12 enters the active layer 5 to a depth of between 0.1 μm and 0.5 μm.

The P-type dopants of the doped region 12 may be zinc atoms and are preferably derived from diffusion from the surface of the upper layer 6 in the direction of the active layer 5.

The doped region 12 individually delimits several cathode areas 13, free of P-type doping, in the upper layer 6. The cathode areas 13 are separated from one another in the upper layer 6 by the doped region 12 in continuous manner i.e. each cathode area 13 is surrounded by the doped area 12 without discontinuity at the upper layer 6. Each of said cathode areas 13 constitutes a cathode of a photodiode. Each cathode area 13 is provided with a contact 14 to a read-out circuit adapted to read said photodiode.

The doped region 12 can therefore have a grid shape as in FIG. 6, or of circles joined together. Other configurations are possible. Also, it is possible to make provision for several diffusion areas 12 surrounding each of the cathodes. Preferably, the doped area 12, in the upper layer 6, surrounds a large number of cathode areas 13 of the array, i.e. more than the majority and preferably all the cathode areas 13 of the array.

At the interfaces between P-type and N-type materials (PN junction), space charge areas are created, also called depletion areas since they are depleted of free carriers. An anode space charge area 15 extends into the active layer 5 from each interface between the doped region 12 of P-type and the active layer 5. Similarly, a buried space charge area 16 extends into the active layer 5 from the interface between said active layer 5 and the buried region 8. FIG. 5 indicates the limits of these space charge areas by dashed lines.

A space charge area 19 is also seen extending into the upper layer 6 from each interface between the doped region 12 of P-type and the upper layer 6, and a space charge area 17 extending into the substrate 4 from the interface between the buried region 8 and said substrate 4.

The electric field generated by a space charge area, oriented from the positive charges (in area N) in the direction of the negative charges (in area P) carries the electrons and the holes in the opposite direction to the phenomenon of charge carrier diffusion. The junction therefore reaches equilibrium since the phenomenon of charge carrier diffusion and the electric field created by this space charge area offset one another.

A space charge area therefore constitutes insulation for the charge carriers, confined within the constituent materials of the PN junction. In an array of the invention, the cathodes are electrically insulated from one another by space charge areas in the active layer 5.

For this purpose, the anode space charge area 15 and the buried space charge area 16 join together in the active layer 5 as illustrated in FIG. 5, so that the areas 18 of the active layer 5 below the cathode area 13 are insulated from one another in terms of charge carrier movement. A cathode area 13 of the upper layer 6 and an area 18 of the active layer 5 facing said cathode area 13 constitutes the cathode of a photodiode. The overlapping of the anode space charge areas 15 and the buried space charge area 16 thereby creates an “N-on-P” photodiode array via electrostatic insulation of the cathodes of said photodiodes.

The extension of a space charge area from the PN junction by which it is generated varies with the charge carrier concentration of the materials of the PN junction i.e. with the dopant concentration thereof. The doping level of P-type dopants in the doped region 12 is greater than the doping level of N-type dopants in the active layer 5, for example with a difference of a factor of at least 10. The anode space charge area 15 therefore extends essentially into the active layer 5. For example, the doping level in the doped region 12 is in the order of 10¹⁸ cm⁻³, whilst the active layer 5 has a doping level lower than 10¹⁶ cm⁻³—typically 10¹⁵ cm⁻³—, and the anode space charge area 12, in the absence of polarization, extends by 1 μm into the active layer 5 from the interface between said active layer 5 and the doped region 12. Similar for the buried space charge area 16. Therefore, for an active layer 5 of InGaAs having a thickness of 2 μm, the anode space charge areas 15 and the buried space charge areas 16 join together, even without polarization, at the described concentrations.

It is therefore possible to insulate the cathodes from one another i.e. prevent the passing of charges from one cathode to another cathode, without the doped region 12 reaching the buried region 8, by means of the continuity of the space charge areas around each area 18 of the active layer 5 free of P-type doping. However, in the absence of polarization, the extension of a space charge area from a PN junction remains limited, which means that this insulation can only be achieved with an active layer 5 of narrow thickness, or by limiting the residual distance d1 between the doped region 12 and the buried region 8 to less than the extension of their respective space charge areas in the absence of polarization.

So that it is possible to increase the thickness of the active layer 5, and hence improve the quantum yield thereof, whilst maintaining this insulation, without the depth of entry of the doped region 12 into the active layer 5 being too great however, it is possible to bias the PN junctions. The extension of a space charge area from the PN junction by which it is generated also varies with the voltages applied either side of the PN junction i.e. with the polarization of said junction. In particular, reverse bias i.e. with a higher potential applied to the cathode than to the anode, allows increased extension of a space charge area. It is then possible via reverse bias to cause the space charge areas to join up via their extension.

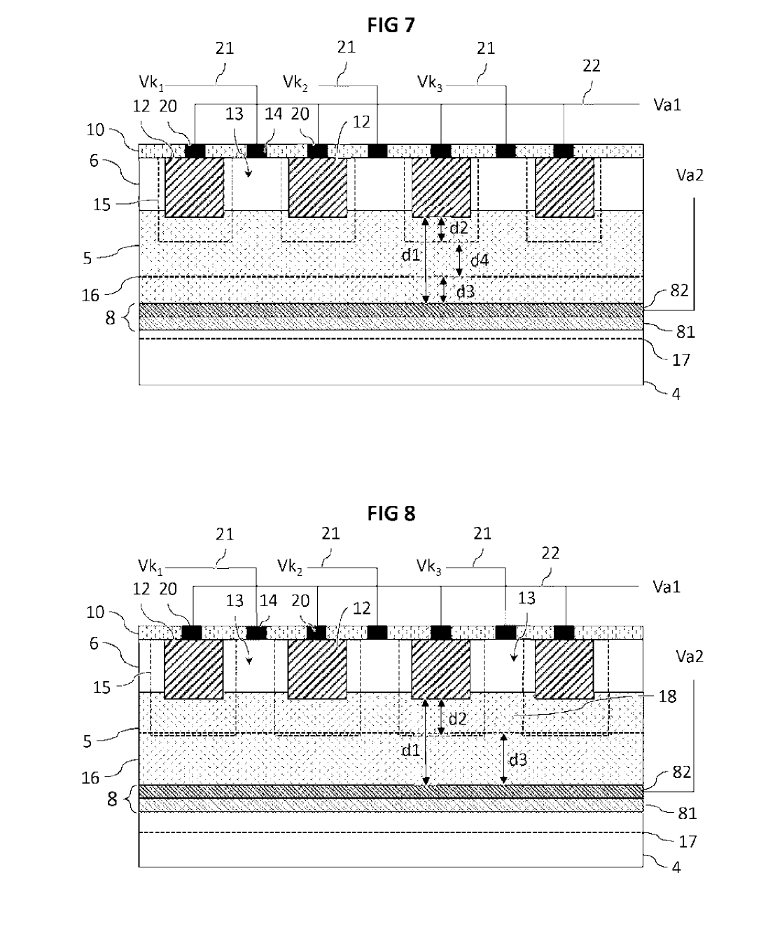

FIGS. 7 and 8 illustrate one embodiment in which bias means are used to apply voltages to the cathodes and anode so as to extend their respective space charge areas until they join together. FIG. 7 illustrates a configuration in which no reverse bias is applied to the PN junctions, and FIG. 8 shows a configuration in which the PN junctions are reverse biased.

The structure of the array is similar to that described with reference to FIGS. 5 and 6. As previously, the doped region 12 and the buried region 8 do not touch each other and are separated by a portion of the active layer 5 by a nonzero distance d1. The anode space charge area 15 extends into the active layer 5 over a distance d2 from the interface between the doped region 12 and said active layer 5. The buried space charge area 16 extends into the active layer 5 over a distance d3 from the interface between the buried region 8 and said active layer 5. Contrary to the preceding embodiment however, these two space charge areas 15, 16 do not join together in the absence of polarization, this giving d1>d2+d3. More specifically the buried space charge area 16 and the anode space charge area 15 are separated by the active layer 5 over a distance d4, so that d1=d2+d3+d4.

In addition, each cathode area 13 of the upper layer 6 is provided with a contact 14 and connectors 21 connecting said contact 14 with a power source (not illustrated), constituting cathode bias means. The contact connected to the power source is preferably the same as the one adapted for connection to the read-out circuit, but it may be different.

Also, the doped region 12 is provided with at least one contact 20, optionally with several contacts 20, and connectors 22 connecting said contact 22 with a power source (not illustrated) constituting anode bias means.

Therefore, each cathode area 13 is connected to cathode bias means adapted to apply a first voltage Vk to each of the cathode areas 13, and the doped area 12 is connected to anode bias means adapted to apply a second voltage Va1 to said doped area 12. In the Figures, the first voltage is denoted Vk₁, Vk₂, Vk₃, Vk₄ to illustrate the independency between the first voltages of each cathode. It is to be noted that the first voltage Vkᵢ at a cathode may correspond to the voltage representing exposure of the photodiodes to light, that is read by the read-out circuits. Each photodiode may therefore have a voltage that varies differently as a function of its own exposure. In all cases, the first voltage Vk varies over a range between a minimum cathode voltage Vkₘᵢₙ and maximum cathode voltage Vkₘₐₓ.

The first voltage Vk and the second voltage Va1 have different values. The difference in value between the first voltage Vk and second voltage Va1 determines the extension of the anode space charge area 15 into the active layer 5, and in particular the distance d2 over which the anode space charge area 15 extends into the active layer 5 from the interface between the doped region 12 and said active layer 5. For example, a difference of 1 V between the value of the first voltage Vk and the value of the second voltage Va1 allows an increase of 1 μm in distance d2 for a doped region 12 doped with zinc at 10¹⁸ cm⁻³ and for an active layer 5 doped with N dopants at 10¹⁵ cm⁻³.

The second voltage Va1 is chosen to be sufficiently lower than the minimum cathode voltage Vkₘᵢₙ so that the anode space charge area 15 extends into the active layer 5 as far as the buried space charge area 16. This provides insulation of the areas 18 of the active layer 5 by the space charge areas in FIG. 5.

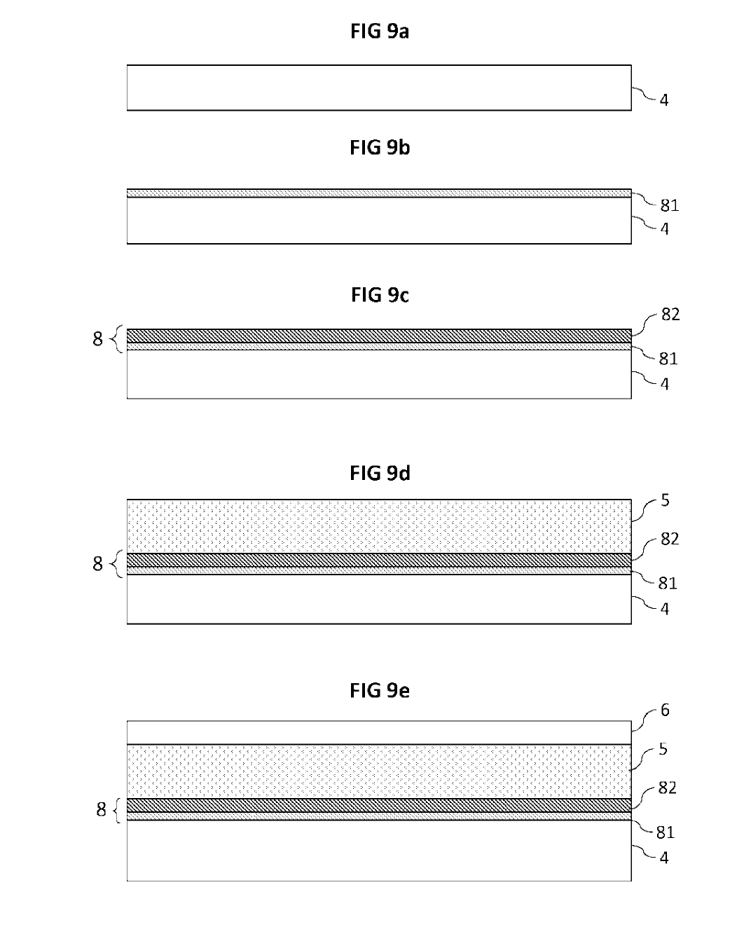

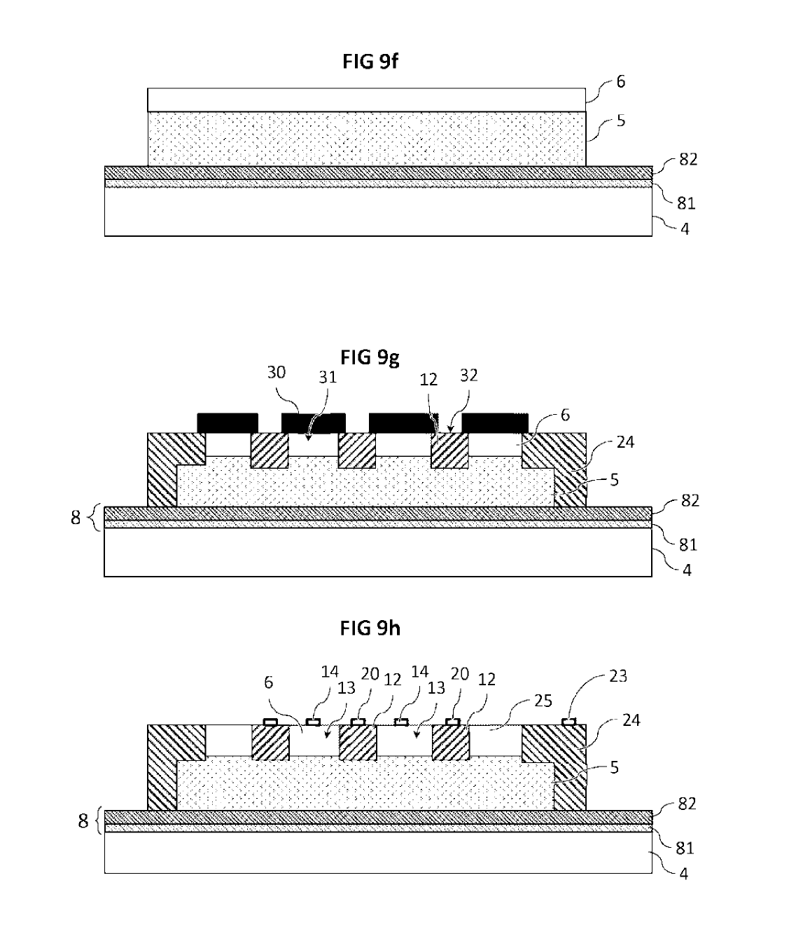

The buried region 8 can also be connected to bias means adapted to apply a third voltage Va2 to said buried region 8. To avoid having to connect the buried region 8 via an interconnect hole, this connection is preferably obtained via the periphery of the photodiode array. For this purpose, a P-doped peripheral area 24 of the array extends from the surface of the array i.e. the upper part 6 as far as the buried layer 8. This P-doped peripheral area 24 corresponds to the doping e.g. by diffusion of the peripheral sides of the active layer 5 and upper layer 6. The peripheral area 24 is provided with a contact 23 (see FIGS. 6 and 9h) and connectors connecting said contact 23 with a power source (not illustrated) delivering the third voltage Va2. Between the peripheral area 24 and the doped region 12 there extends a buffer region 25 of the upper layer 6, which insulates the peripheral area 24 from the doped region 12.

The first voltage Vk and the third voltage Va2 have different values. The difference in value between the first voltage Vk and the third voltage Va2 determines the extension of the buried space charge area 16 into the active layer 5, and in particular the distance d3 over which the buried space charge area 16 extends into the active layer 5 from the interface between the buried region 8 and said active layer 5.

The third voltage Va2 is chosen to be sufficiently lower than the minimum cathode voltage Vkₘᵢₙ so that the buried space charge area 16 extends into active layer 5 as far as the anode space charge area 15. The second voltage Va1 and the third voltage Va2 may have the same values, but preferably have different values.

The doped region 12 of P-type and the upper layer 6 of N-type are in contact and their respective doping levels are relatively high compared with the doping of the active layer 5: for example 10¹⁵ to 10¹⁸ cm⁻³ for the upper layer 6, and 10¹⁸ cm⁻³ with Zn for the doped region 12, against 10¹³ to 10¹⁷ cm⁻³ for the active layer 5, bearing in mind that the doping of the upper layer 6 is preferably at least ten times greater than the doping of the active layer 5. It follows that a difference in value between the first voltage Vk and the second voltage Va1 that is too high may generate strong leakage currents in the PN junction constituted by the interface between the doped region 12 and the upper layer 6. On the other hand, the doping level in the active layer 5 being much lower, there is less risk of generating strong leakage currents in the PN junction constituted by the interface between the buried region 8 and the upper layer 6.

Therefore, the difference in value between the minimum cathode voltage Vkₘᵢₙ and the second voltage Va1 is preferably lower than the difference between the minimum cathode voltage Vkₘᵢₙ and the third voltage Va2. For example, returning to the preceding examples, with minimum polarization of 0.3 V between the minimum cathode voltage Vkₘᵢₙ and the second voltage Va1, and minimum polarization of 1.8 V between the minimum cathode voltage Vkₘᵢₙ and the third voltage Va2, it is possible to cause the space charge areas 15, 16 to join together in an active layer of 3 μm thickness. FIG. 6 shows the array of FIG. 5 in a configuration in which the applied voltages allow the anode space charge area 15 and the buried space charge area 16 to join together in the active layer 5.

When insulation is obtained, we therefore have the sum:
of distance d2 over which the anode space charge area 15 extends into the active layer 5 from the interface between the doped region 12 and said active layer 5; and
of distance d3 over which the buried space charge area 16 extends into the active layer 5 from the interface between the buried region 8 and said active layer 5, that is greater than the distance d1 separating the doped region 12 and the buried region 8 in the active layer 5.

To limit the applied voltages, it is preferable however that the distance d4 separating the anode space charge area 15 from the buried space charge area 16 in the active layer 5, in the absence of polarization, should not be too great. Preferably distance d4 is twice shorter than the minimum between d2 and d3 in the absence of polarization:

d4<min(d2,d3).

It is to be noted that it is not necessary that both the second voltage Va1 and the third voltage Va2 should be lower than the lower limit of the variation range of the first voltage Vk, i.e. lower than the minimum cathode voltage Vkₘᵢₙ. It is sufficient that one thereof is sufficiently lower than this minimum cathode voltage Vkₘᵢₙ to ensure sufficiently large extension of its space charge area so that it joins up with the other space charge area. The other anode voltage could then be slightly higher than the first voltage without interrupting the insulation of the cathodes for as long as the space charge areas . . . . However, to be on the safe side, it is better if both the second voltage Va1 and the third voltage Va2 are lower than the lower limit of the variation range of the first voltage Vk, i.e. lower than the minimum cathode voltage Vkₘᵢₙ.

Irrespective of the method used to cause the anode space charge area 15 and the buried space charge area 16 to join together, (via doping and/or polarization) the cathodes are separated from one another by continuity of space charge area. The photoelectrons are therefore repelled towards the cathode and confined therein. In addition, it is not necessary for the active layer 5 to be highly doped: the lifetime of charge carriers in the active layer 5 and hence in the cathode, is extended. In this manner, detection is improved compared with the solution proposed in U.S. Pat. No. 8,610,170 B2. Also, the doped region 12 does not need to pass through the entire thickness of the active layer 5, and the lateral diffusion of dopants forming this doped region 12 therefore remains limited, thereby allowing a reduction in the spatial pitch of the photodiodes in comparison with the solution proposed in U.S. Pat. No. 8,610,170 B2, and hence an increase in the resolution of the array.

With reference to FIGS. 9a to 9h, different steps are illustrated of a method to manufacture an array according to any of the previously described embodiments.

At a first step, illustrated in FIG. 9a, an indium phosphide substrate 4 is provided having conductivity of N-type that can be silicon doped. At a second step illustrated in FIG. 9b, a surface area 81 on the surface of the substrate 4 is doped by diffusion of P-type dopants, typically zinc. At a third step illustrated in FIG. 9c, an epitaxial InGaAs buffer layer 82 doped with P-type dopants typically zinc is formed on the surface of the surface area 81. It is also possible not to dope the surface area 81 on the surface of the substrate 4 at the second step, and to conduct doping thereof at the same time as the buffer layer 82. Another solution is to P-doped solely the surface area 81 of the substrate 4 and to form the buffer layer and/or active layer thereupon, the doping of these layers at the interface with the substrate 4 taking place by thermal diffusion of dopants. The combination of the surface area 81 of the substrate 4 and of the layer 82 above said surface area 81 of the substrate 4 therefore constitutes a buried region 8 of P-type, being defined by P-type doping.

At a fourth step illustrated in FIG. 9d, an active layer 5 of InGaAs is formed, preferably N-doped, above the buried region 8, also preferably via epitaxy. At a fifth step illustrated in FIG. 9e, an upper layer 6 in InP is formed, N-doped e.g. with silicon, also preferably via epitaxy, above the active layer 5.

At a sixth step illustrated in FIG. 9f, selective etching can be performed on the upper layer 6 and active layer 5 to remove the entire thickness thereof on the periphery of the array. This exposes the underlying buried region 8, to facilitate the connection thereof.

At a seventh step illustrated in FIG. 9g, a mask 30 is positioned defining a plurality of masking areas 31 on the surface of the upper layer 6, intended to be the surfaces of the cathode areas 13 of the upper layer 6, and defining a plurality of exposed areas 32 on the surface of the upper layer 6 intended to be the surfaces of the doped area 12. The mask also leaves exposed the peripheral sides of the active layer 5 and upper layer 6 exposed by etching at the sixth step.

Dopants of P-type are then diffused through the exposed areas 32 in the upper layer 6 and in the active layer 5 to define the doped region 12 of P-type so that the doped region 12 extends from the upper layer 6 as far as into the active layer 5 without reaching the buried region 8 or the substrate 4. The diffusion of dopants is therefore interrupted before the doped region 12 reaches the buried region 8. On peripheral sides of the active layer 5 and of the upper layer 6. a peripheral P-doped area 24 is also created extending from the surface of the array i.e. the upper part 6 as far as the buried layer 8.

At an eighth step illustrated in FIG. 9h, the contacts 14 of the cathode areas 13 are formed, as well as the anode contact(s) 20 of the doped region 12, and the contact 23 of the peripheral area 24. The buffer region 25 between the doped region 12 and the peripheral area 24 is not provided with a contact. These contacts 14, 20, 23 are then connected to their respective bias means by means of connectors to obtain an array similar to those in FIGS. 5 to 8. It is possible to deposit a passivation layer 10 on the surface of the upper layer 6. The contacts 14 of the cathodes are connected to a read-out circuit, for example as shown in FIG. 2 according to the prior art.

The invention is not limited however to the embodiment described and illustrated in the appended Figures. Modifications remain possible, in particular in respect of the forming of the various elements or substitution thereof by technical equivalents, without departing from the scope of protection of the invention.

1. A photodiode array comprising:
an indium phosphide substrate (4);
an active layer (5) of indium gallium arsenide InGaAs above the substrate (4) and having conductivity of a first type;
an upper layer (6) in indium phosphide above the active layer (5) and having conductivity of the first type;
a buried region (8) defined by doping of a second type, at an interface between the substrate (4) and the active layer (5),
characterized in that said array comprises an anode common to the photodiode array, formed by a doped region (12) of the second type in the upper layer (6) and in the active layer (5), said doped region (12) extending from the upper layer (6) as far as into the active layer (5) without reaching the buried region (8), said doped region (12) and said buried region (8) being separated by the active layer (5) by a nonzero distance (d1),
said doped region (12) delimiting several cathode areas (13), free of the second type doping in the upper layer (6), each of said cathode areas (13) being continuously separated from the other cathode areas (13) by the doped region (12).

2. The array according to claim 1, wherein an anode space charge area (15) extends into the active layer (5) from each interface between the doped region (12) of the second type and the active layer (5), and a buried space charge area (16) extends into the active layer (5) from the interface between said active layer (5) and the buried region (8), the anode space charge area (15) and the buried space charge area (16) joining together in the active layer (5), so that areas (18) of the active layer (5) underneath the cathode areas (13) of the upper layer (6) are insulated from one another continuously by said space charge areas.

3. The array according to claim 1, wherein each cathode area (13) of the upper layer (6) is connected to bias means (21) adapted to apply a first voltage (Vk) to said cathodes, and wherein the doped area (12) is connected to bias means (22) adapted to apply a second voltage (Va1) to said doped area (12), the first voltage (Vk) and the second voltage (Va1) being of different values, the difference in value between the first voltage (Vk) and the second voltage (Va1) determining the extension of the anode space charge area (15) into the active layer (5), the first voltage varying over a range between a minimum cathode voltage and a maximum cathode voltage, the second voltage (Va1) being chosen to be sufficiently lower than the minimum cathode voltage so that the anode space charge area (15) extends into the active layer (5) as far as the buried space charge area (16).

4. The array according to claim 1, wherein each cathode area (13) of the upper layer (6) is connected to bias means (21) adapted to apply a first voltage (Vk) to said cathodes, and wherein the buried region (8) is connected to bias means adapted to apply a third voltage (Va2) to said buried region (8), the first voltage (Vk) and the third voltage (Va2) being of different values, the difference in value between the first voltage (Vk) and the third voltage (Va2) determining the extension of the buried space charge area (16) into the active layer (5), the first voltage varying over a range between a minimum cathode voltage and a maximum cathode voltage, the third voltage (Va2) being chosen to be sufficiently lower than the first voltage (Vk) so that the buried space charge area (16) extends into the active layer (5) as far as the anode space charge area (15).

5. The array according to claim 4, wherein the difference in value between the minimum cathode voltage and the second voltage (Va1) is lower than the difference in value between the minimum cathode voltage and the third voltage (Va2).

6. The array according to claim 2, wherein a distance (d4) separating the anode space charge area (15) and the buried space charge area (16) in the active layer (5) in the absence of polarization is shorter than twice the minimum distance between:
a distance (d2) over which the anode space charge area (15) extends into the active layer (5) from the interface between the doped region (12) and said active layer (5) in the absence of polarization; and
a distance (d3) over which the buried space charge area (16) extends into the active layer (5) from the interface between the buried region (8) and said active layer (5) in the absence of polarization.

7. The array according to claim 1, wherein the cathode areas (13) of the upper layer (6) that are delimited by the doped region (12) of the second type, are doped with dopants of the first type.

8. The array according to claim 1, wherein the doped region (12) of the second type extends into the active layer (5) from the upper layer (6) over a depth less than one quarter of the thickness of said active layer (5).

9. A sensor comprising a photodiode array according to claim 1, and a readout circuit connected to contacts (14) of the cathode areas (13) to read the photodiodes of said array.

10. A method for manufacturing an array according to claim 1, comprising the steps of:
providing an indium phosphide substrate (4) having conductivity of a first type;
forming a buried region (8) having conductivity of a second type above said substrate (4);
forming an active layer (5) having conductivity of the first type above the buried region (8),
forming an upper layer (6) having conductivity of the first type above the active layer (5),
positioning a mask (30) defining a plurality of masking areas (31) on the surface of the upper layer (6) and a plurality of exposed areas (32) on the surface of the upper layer (6),
diffusing dopants of the second type through the exposed areas (32) in the upper layer (6) and in the active layer (5) to define a doped region (12) of the second type facing said exposed areas so that the doped region (12) extends from the upper layer (6) as far as into the active layer (5) without reaching the buried region (8), said doped region (12) and said buried region (8) being separated by a nonzero distance, said doped region (12) delimiting several cathode areas (13) of the upper layer (6) facing the masking areas (31), each of said cathode areas (13) being continuously separated from the other cathode areas (13) by the doped region (12).
